(19) United States
(12) Patent Application Publication
(10) Pub. No.: US 2011/0182312 A1
(43) Pub. Date: Jul. 28, 2011

(54) LASER DIODE USING ASYMMETRIC QUANTUM WELLS

(75) Inventors: Wei-Li Chen, Yuanlin Township (TW); Shih-Chang Lin, Hsinchu City (TW)

(73) Assignee: National Changhua University of Education, Changhua City (TW)

(21) Appl. No.: 12/845,855

(22) Filed: Jul. 29, 2010

(30) Foreign Application Priority Data
Jan. 25, 2010 (TW) 099101939

(51) Int. Cl. H01S 5/343; H01S 5/34

(52) U.S. Cl. 372/45.01

(57) ABSTRACT

A laser diode using asymmetric quantum wells includes a N-type semiconductor, a P-type semiconductor, a first quantum well structure, and a second quantum well structure. The first quantum well structure is between the N-type semiconductor and the P-type semiconductor, and includes at least one first quantum well having a first thickness. The second quantum well structure is between the N-type semiconductor and the P-type semiconductor, and includes at least one second quantum well having a second thickness greater than the first thickness of the first quantum well and a lasing wavelength greater than that of the first quantum well. The second quantum well is formed with a spike therein.

### CROSS-REFERENCE TO RELATED APPLICATION

This application claims priority from Taiwanese Patent Application No. 099101939, filed on Jan. 25, 2010.

### BACKGROUND OF THE INVENTION

1. Field of the Invention

The invention relates to a laser diode, and more particularly to a laser diode using asymmetric quantum wells.

2. Description of the Related Art

Multiple quantum wells of uniform thickness have been employed in a conventional laser diode. To extend the gain bandwidth, quantum wells of different thicknesses are used in an asymmetric quantum well structure. Such a laser with a broad bandwidth can be used in, for example, a wavelength division multiplexing device which involves a technology of producing multiple channels on a common substrate. However, the gain spectrum of the conventional laser diode with asymmetric quantum wells is sensitive to driving current and is not flat, which leads to non-uniform lasing strength between channels.

Referring to FIG. 1, a conventional laser diode is composed of three first quantum wells 10 and a second quantum well 11 with a thickness greater than that of each of the first quantum wells 11. That is, the thickness of each of the first quantum wells 10 is 4.3 nm, and the thickness of the second quantum well 11 is 9 nm. Correspondingly, the confinement energy of each of the first quantum wells 10 is 137 meV, and the confinement energy of the second quantum well 11 is 200 meV. The first quantum wells 10 are proximate to a N-type semiconductor, and the second quantum well 11 is proximate to a P-type semiconductor. The lasing wavelength corresponding to the first quantum wells 10 is 1.25 μm, and the lasing wavelength corresponding to the second quantum well 11 is 1.365 μm. Such a laser diode is referred to as an A1 type hereinafter.

FIG. 3 shows the current density curve of the A1 type of the laser diode. The electron current flows in a direction from the N-type semiconductor to the P-type semiconductor via the first quantum wells 10 and the second quantum well 11. The hole current flows in a direction counter to the direction of the electron current. It is noted that most of the carriers are captured in the second quantum well 11 followed by stimulated recombination. Therefore, the carriers cannot be distributed evenly in the first and second quantum wells 10, 11, and accordingly, most of the laser photons are produced from the second quantum well 11, which is best shown in FIG. 4, in which the stimulated recombination rate of the second quantum well 11 of the A1 type of the laser diode is significantly greater than that of the first quantum well 10 of the A1 type of the laser diode.

Referring to FIG. 5, which shows the curves of gain versus wavelength at an input current of 60 mA of various types of the laser diodes, the difference between the peak value and the local minimum value of the gain of the A1 type of the laser diode is relatively large.

In view of the aforesaid, although a wide lasing spectrum can be provided by the conventional laser diode using asymmetric quantum wells, a flat gain spectrum cannot be obtained due to the non-uniform distribution of the carriers in the first and second quantum wells 10, 11.

### SUMMARY OF THE INVENTION

The object of the present invention is to provide a laser diode using asymmetric quantum wells and possessing optical performances superior to those of the prior art.

According to an aspect of this invention, a laser diode using asymmetric quantum wells includes a N-type semiconductor, a P-type semiconductor, a first quantum well structure, and a second quantum well structure. The first quantum well structure is formed between the N-type semiconductor and the P-type semiconductor, and includes at least one first quantum well having a first thickness. The second quantum well structure is formed between the N-type semiconductor and the P-type semiconductor, and includes at least one second quantum well having a second thickness greater than the first thickness of the first quantum well and a lasing wavelength greater than that of the first quantum well. The second quantum well is formed with a spike therein.

According to another aspect of this invention, a laser diode having asymmetric quantum wells includes a N-type semiconductor, a P-type semiconductor, a first quantum well structure, a second quantum well structure, and a third quantum well structure. The first quantum well structure is formed between the N-type semiconductor and the P-type semiconductor, and includes at least one first quantum well having a first thickness. The second quantum well structure is formed between the N-type semiconductor and the P-type semiconductor, and includes at least one second quantum well having a second thickness greater than the first thickness of the first quantum well and a lasing wavelength greater than that of the first quantum well. The third quantum well structure is formed between the N-type semiconductor and the P-type semiconductor, and includes at least one third quantum well having a third thickness greater than the first thickness of the first quantum well and less than the second thickness of the second quantum well and a lasing wavelength greater than that of the first quantum well and less than that of the second quantum well. The third quantum well is formed with a spike therein.

### BRIEF DESCRIPTION OF THE DRAWINGS

Other features and advantages of the present invention will be described and explained in the following detailed description of the preferred embodiments of the invention, with reference to the associated drawings, in which:

FIG. 1 illustrates an energy band diagram of a conventional laser diode using asymmetric quantum wells;

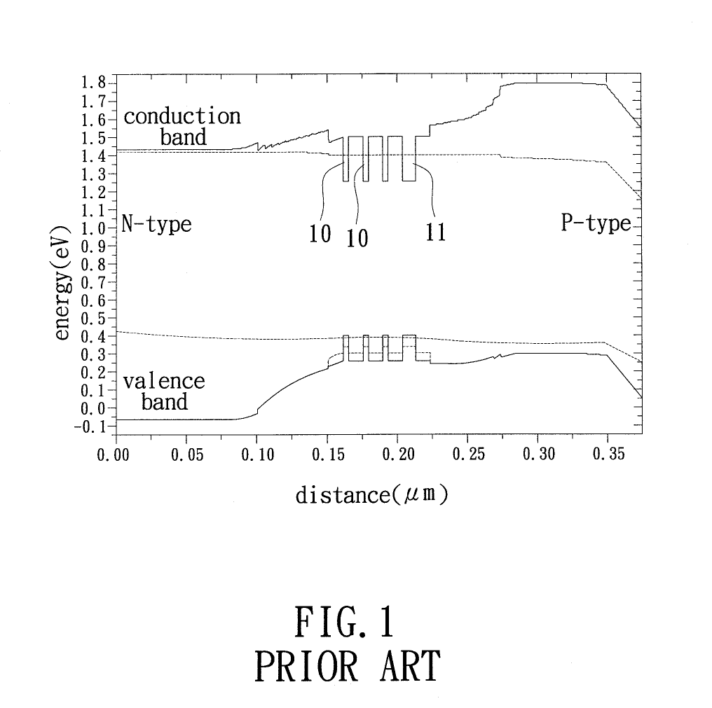

FIG. 2 illustrates an energy band diagram of a first preferred embodiment of a laser diode using asymmetric quantum wells according to this invention;

FIG. 3 illustrates plots of electron current density and hole current density for the conventional laser diode and three examples of the first preferred embodiment;

FIG. 4 illustrates plots of stimulated recombination rate versus current for the conventional laser diode and the examples of the first preferred embodiment;

FIG. 5 illustrates plots of gain versus wavelength for the conventional laser diode and the examples of the first preferred embodiment at an input current of 60 mA;

FIG. 6 illustrates an energy band diagram of an example of a second preferred embodiment of a laser diode using asymmetric quantum wells according to this invention;

FIG. 7 illustrates plots of electron current density and hole current density for the example of the second preferred embodiment;

FIG. 8 illustrates a gain versus wavelength plot for the example of the second preferred embodiment at an input current of 60 mA;

FIG. 9 illustrates an energy band diagram of another example of the second preferred embodiment; and

FIG. 10 illustrates a gain versus wavelength plot for the another example of the second preferred embodiment at an input current of 60 mA.

### DETAILED DESCRIPTION OF THE PREFERRED EMBODIMENTS

Before the present invention is described in great detail, it should be noted that like elements are denoted by the same reference numerals throughout the disclosure.

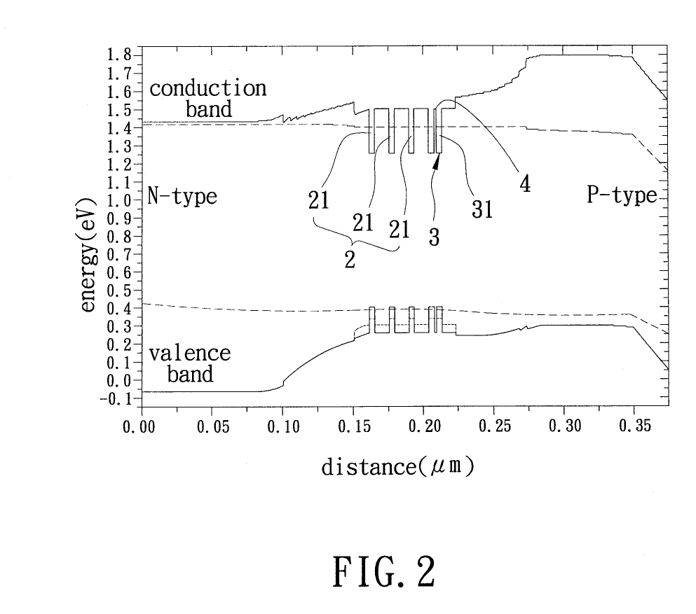

Referring to FIG. 2, the first preferred embodiment of a laser diode using asymmetric quantum wells according to this invention includes a N-type semiconductor, a P-type semiconductor, a first quantum well structure 2, and a second quantum well structure 3 with a spike 4.

The first and second quantum well structures 2, 3 are preferably made of the same material of Group II-VI semiconductors, Group III-V semiconductors, or Group IV semiconductors. More preferably, the first and second quantum well structures 2, 3 are made of InₓGa_{1-x-y}Al_{y}As, wherein x, y, and 1-x-y range from 0 to 1. Most preferably, the first and second quantum well structures 2, 3 are made of a composition of In_{0.68}Ga_{0.19}Al_{0.14}As. The spike 4 is made of a material without strain induced by lattice mismatch, and is preferably made of In_{0.52}Ga_{0.209}Al_{0.271}As or In_{0.52}Ga_{0.339}Al_{0.141}As. Since the first and second quantum well structures 2, 3 are made of the same material, it is only necessary to adjust the thickness of the first and second quantum well structures 2, 3 during the thin film epitaxy process, and the complexity in the epitaxy attributed to the use of different materials can be avoided. In addition, in the preferred embodiment, a barrier with a thickness of 10 nm and made of In_{0.438}Ga_{0.292}Al_{0.27}As is used to avoid coupling of the wave functions between quantum wells, which may affect the lasing wavelength.

The first quantum well structure 2 is between the N-type semiconductor and the P-type semiconductor, and includes three first quantum wells 21, each of which has a first thickness. In the preferred embodiment, the first quantum well structure 2 is proximate to the N-type semiconductor, and the first thickness of each of the first quantum wells 21 is 4.3 nm.

The second quantum well structure 3 is between the N-type semiconductor and the P-type semiconductor, and includes a second quantum well 31 having a second thickness greater than the first thickness of the first quantum well 21 and a lasing wavelength greater than that of the first quantum well 21. In the preferred embodiment, the second quantum well structure 3 is proximate to the P-type semiconductor, and the second thickness of the second quantum well 31 is 9 nm.

A spike 4 is formed in the second quantum well 31. Although it raises the quantized energy level of the second quantum well 31, the lasing wavlength of the second quantum well 31 is longer than that of the first quantum well 21. The thickness of the spike 4 ranges from 1 monolayer to 10 monolayers. In the preferred embodiment, the thickness of the spike 4 is 2 monolayers or 4 monolayers, i.e., 0.586 nm or 1.172 nm.

In the preferred embodiment, three examples of the laser diode are illustrated to be compared with the conventional A1 type of the laser diode described above, and are referred to as A2 type, A3 type, and A4 type, respectively. In the A2 type of the laser diode, the thickness of the spike 4 is 2 monolayers, and the composition of the spike 4 is In_{0.52}Ga_{0.209}Al_{0.271}As. In the A3 type of the laser diode, the thickness of the spike 4 is identical to that of the spike 4 of the A2 type, and the composition of the spike 4 is In_{0.52}Ga_{0.339}Al_{0.141}As. In the A4 type of the laser diode, the composition of the spike 4 is identical to that of the spike 4 of the A3 type, and the thickness of the spike 4 is 4 monolayers.

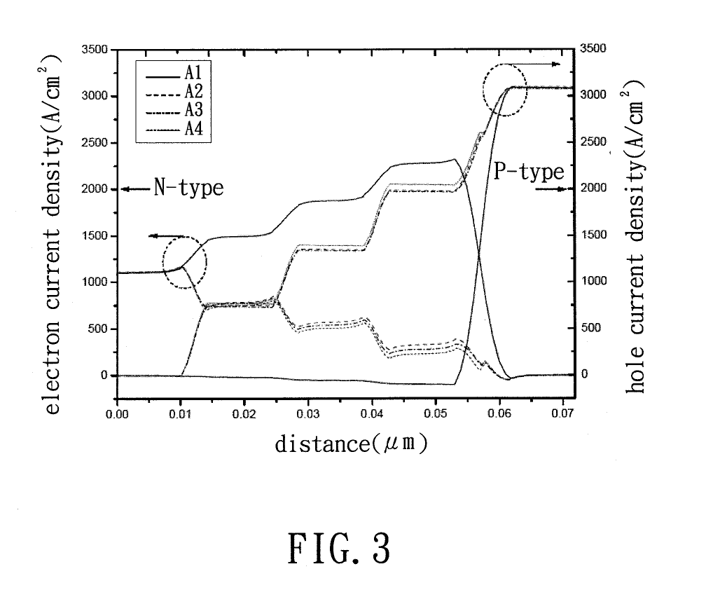

Referring to FIGS. 3, 4, and 5, the conventional A1 type of the laser diode is compared to the A2, A3, and A4 types of the laser diode of the preferred embodiment in terms of various optical and electrical performances.

Specifically referring to FIG. 3, the electron current flows in a direction from the N-type semiconductor to the P-type semiconductor via the first quantum wells 21 and the second quantum well 31. The hole current flows in a direction counter to the direction of the electron current. In the A2, A3, and A4 types of the laser diode of the preferred embodiment, there is no disadvantage of uneven distribution of the carrier recombination encountered in the conventional A1 type of the laser diode. The curves for the electron current density and the hole current density of the A2, A3, and A4 types of the laser diode of the preferred embodiment are regularly stepped, which means that the electrons and the holes can be distributed relatively evenly and recombined favorably in both the first and second quantum wells 21, 31. By forming the spike 4 in the second quantum well 31, the capture of carriers and stimulated recombination in the second quantum well 31 are inhibited. Therefore, the capture of carriers and stimulated recombination in the first quantum well 21 are enhanced, which results in a more even distribution of the stimulated recombination among two types of quantum wells.

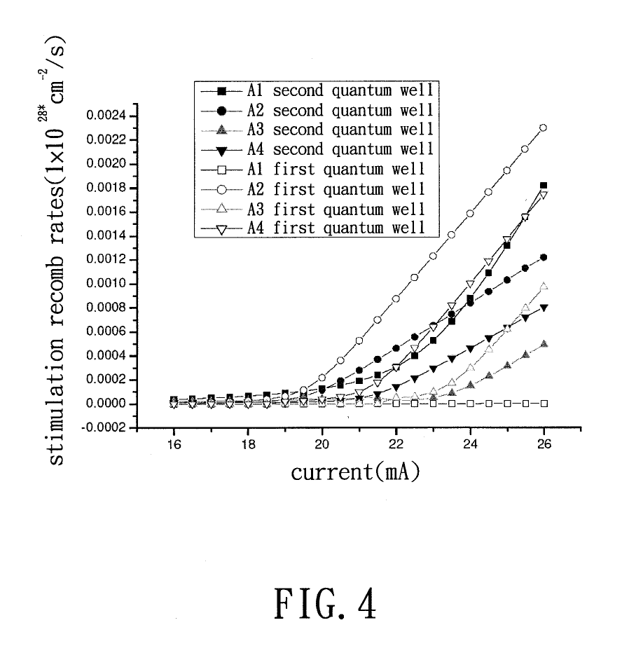

Specifically referring to FIG. 4, in the A2, A3, and A4 types of the laser diode of the preferred embodiment, since the carriers can be distributed relatively evenly in the first and second quantum wells 21, 31 due to the formation of the spike 4 in the second quantum well 31, the difference of the stimulated recombination rate between the first and second quantum wells 21, 31 is relatively small as compared to that of the conventional A1 type of the laser diode in which the stimulated recombination rate for the first quantum well 10 is about 0 and the stimulated recombination rate of the second quantum well 11 is significantly greater than that of the first quantum well 10.

Furthermore, in the A2, A3, and A4 types of the laser diode of the preferred embodiment, the first quantum well 21 has a thickness smaller than that of the second quantum well 31. Therefore, the first quantum well 21 has a relatively large differential gain so that the stimulated recombination rate for the first quantum well 21 is larger than that for the second quantum well 31. Moreover, since the carriers can be stimulated to recombine in the first and second quantum wells 21, 31, the laser slope efficiency is increased.

Specifically referring to the stimulated recombination rate in A3 structure in FIG. 4, the stimulated recombination rate of the second quantum well 31 is larger than that of the first quantum well 21 when the driving current is below 21 mA, which is still below threshold. As the current is further increased, on the countary, the stimulated recombination rate of the first quantum well 21 is larger than that of the second quantum well 31 due to larger differential gain. Finally the threshold current is lowered because it is dominated by the first quantum well 21 due to larger differential gain. As described above, the A2 and A4 types of laser diodes show similar characteristics.

As described above, in the conventional A1 type of laser diode, most of the carriers are captured and stimulated to recombine in the second quantum well 11. Therefore, the laser is produced primarily from the second quantum well 11 as the current increases to reach the threshold current of the second quantum well 11. Therefore, as shown in the following table, the threshold current for producing the laser in the laser diode of the present invention is lowered as compared to that for the conventional laser diode. The slope efficiency is increased in the laser diode of the present invention because both types of quantum wells are lasing.

TABLE

| Type | A1 | A2 | A3 | A4 |
|---|---|---|---|---|
| Threshold current (mA) | 22.8 | 19.8 | 22.3 | 21.3 |
| Slope efficiency (mW/mA) | 0.416 | 0.454 | 0.453 | 0.453 |

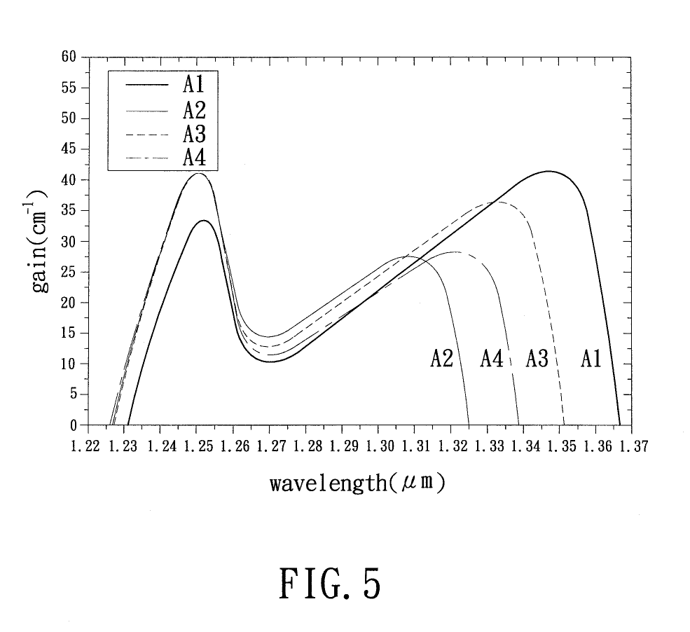

Referring to FIG. 5, the difference between the peak gain value and the local minimum gain value for the A1 type of the laser diode is about 33 cm⁻¹. The difference between the peak gain value and the local minimum gain value for the A2, A3, and A4 types of the laser diode ranges from 25 to 29 cm⁻¹, which is smaller than that of the A1 type of the laser diode. Additionally, the formation of the spike 4 in the second quantum well 31 causes the peak gain wavelength of the second quantum well 31 to be shortened (i.e., blue shifted).

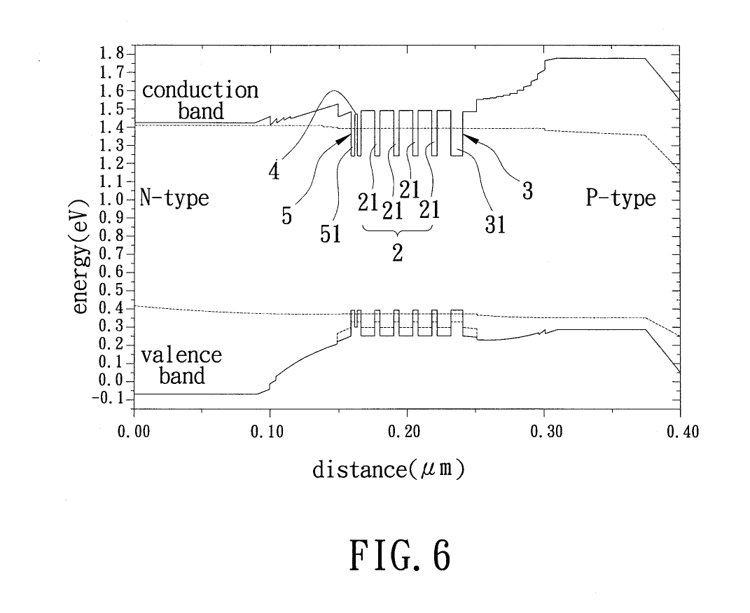

Referring to FIG. 6, the second preferred embodiment of a laser diode using asymmetric quantum wells according to this invention is similar to the first preferred embodiment except that a third quantum well structure 5 is further included in the second preferred embodiment. The third quantum well structure 5 is between the N-type semiconductor and the P-type semiconductor, and includes a third quantum well 51 having a third thickness greater than the first thickness of the first quantum well 21 and less than the second thickness of the second quantum well 31 and a lasing wavelength greater than that of the first quantum well 21 and less than that of the second quantum well 31. In the second preferred embodiment, the spike 4 is formed in the third quantum well 51, rather than in the second quantum well 31.

The lasing wavelength of the third quantum well 51 is located between those of the first quantum well 21 and the second quantum well 31. Since the laser gain attributed to the third quantum well 51 overlaps those attributed to the first and second quantum wells 21, 31, the gain at the lasing wavelength of the third quantum well 51 is greater than those at the lasing wavelengths of the first and second quantum wells 21, 31. In order to flatten the spectrum, the spike 4 is formed in the third quantum well 51, of which the lasing wavelength is located around the spectrum central wavelength, so as to inhibit the gain attributed to the third quantum well 51 and to enhance the even distribution of carriers.

Two examples are illustrated for the second preferred embodiment. In the first example, the first quantum well structure 2 includes four first quantum wells 21, and is referred to as B1 type of the laser diode. In the second example, the first quantum well structure 2 includes three first quantum wells 21, and is referred to as B2 type of the laser diode. In the B1 type of the laser diode, the first thickness of the first quantum well is 4.3 nm, the second thickness of the second quantum well is 9 nm, the third thickness of the third quantum well is 7.5 nm, and the thickness of the spike is 0.879 nm (i.e., 3 monolayers). In the B2 type of the laser diode, the first thickness of the first quantum well is 4.5 nm, the second thickness of the second quantum well is 9 nm, the third thickness of the third quantum well is 7.5 nm, and the thickness of the spike is 0.879 nm.

Referring to FIGS. 6, 7, and 8, in the B1 type of the laser diode, the third quantum well structure 5 is proximate to the N-type semiconductor, the second quantum well structure 3 is proximate to the P-type semiconductor, and the first quantum well structure 2 is formed between the second and third quantum well structures 3, 5.

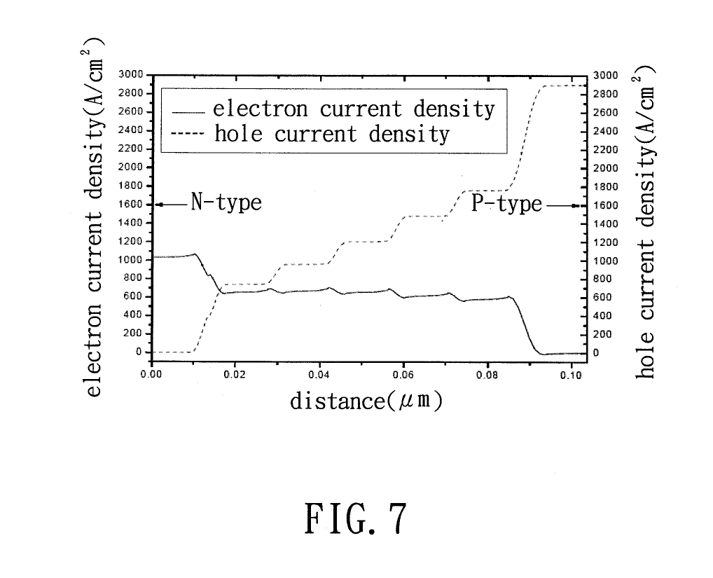

Specifically referring to FIG. 7, the curves for the electron current density and the hole current density of the B1 type of the laser diode of the second preferred embodiment is regularly stepped, which means that the electrons and the holes can be distributed relatively evenly and recombined favorably in the first, second, and third quantum wells 21, 31, 51.

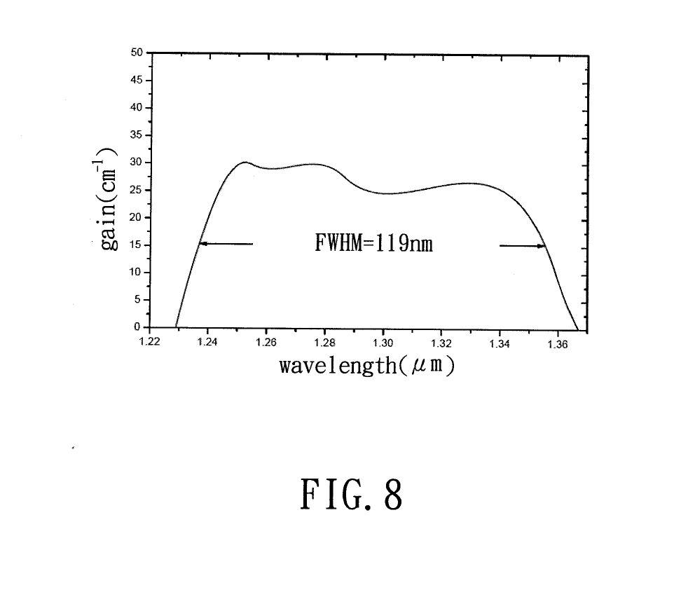

Specifically referring to FIG. 8, for the B1 type of the laser diode, the peak gain value is 29.96 cm⁻¹, the full width at half maximum (FWHM) is about 119 nm, and the difference between the peak gain value and the local minimum gain value is about 5 cm⁻¹, which means that the spectrum is flattened.

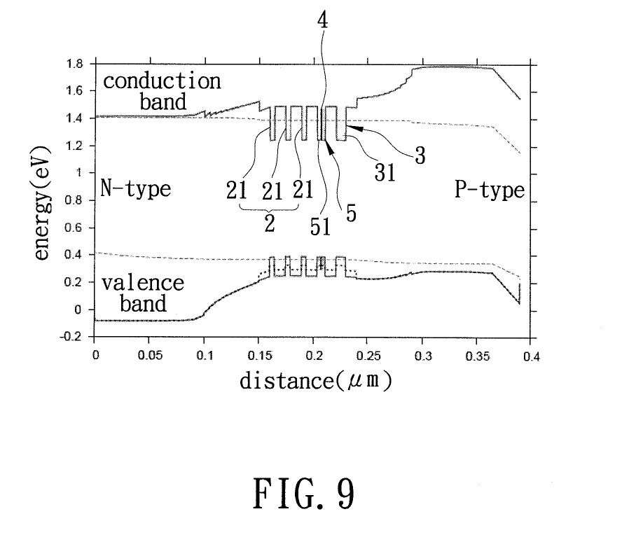

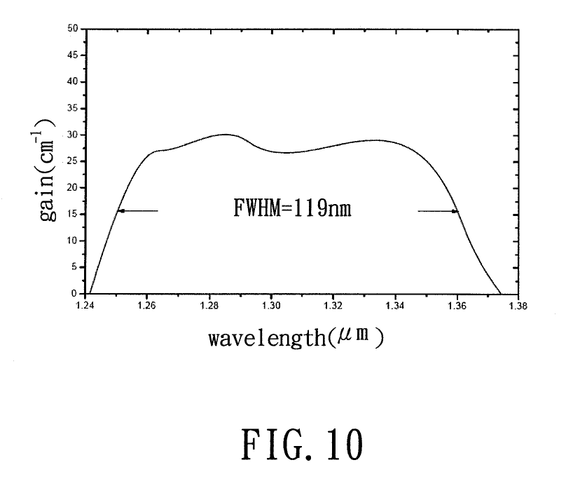

Referring to FIGS. 9 and 10, in the B2 type of the laser diode, the first quantum well structure 2 is proximate to the N-type semiconductor, the second quantum well structure 3 is proximate to the P-type semiconductor, and the third quantum well structure 5 is formed between the first and second quantum well structures 2, 3. As compared to the B1 type of the laser diode, the laser gain attributed to the first quantum wells 21 is reduced due to the reduction in the number of the first quantum wells 21 from four to three. The confinement energy of each of the first quantum wells 21 in the B1 type of the laser diode is 137 meV. The confinement energy of each of the first quantum wells 21 in the B2 type of the laser diode is 142 meV, which is greater than that of each of the first quantum wells 21 in the B1 type of the laser diode. Therefore, the capability of the first quantum wells 21 to capture the carriers and to recombine the carriers via stimulated recombination can be further enhanced in the B2 type of the laser diode as compared to the B1 type of the laser diode. The distribution of the stimulated recombination rates in the first, second, and third quantum wells 21, 31, 51 is more even.

Referring to FIG. 10, for the B2 type of the laser diode, the peak gain value is 30.12 cm⁻¹, the FWHM is about 110 nm, and the difference between the peak gain value and the local minimum gain value is about 3 cm⁻¹, which means that the spectrum is further flattened as compared to the B1 type of the laser diode.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

We claim:

1. A laser diode using asymmetric quantum wells, comprising:
a N-type semiconductor;
a P-type semiconductor;
a first quantum well structure formed between said N-type semiconductor and said P-type semiconductor and including at least one first quantum well having a first thickness; and
a second quantum well structure formed between said N-type semiconductor and said P-type semiconductor and including at least one second quantum well having a second thickness greater than the first thickness of said first quantum well and a lasing wavelength greater than that of said first quantum well, said second quantum well being formed with a spike therein.

2. The laser diode as claimed in claim 1, wherein said spike has a thickness ranging from 1 monolayer to 10 monolayers.

3. The laser diode as claimed in claim 2, wherein the first thickness of said first quantum well is 4.3 nm, the second thickness of said second quantum well is 9 nm, and the thickness of said spike is 0.586 nm or 1.172 nm.

4. The laser diode as claimed in claim 1, wherein said first quantum well structure is proximate to said N-type semiconductor, and said second quantum well structure is proximate to said P-type semiconductor.

5. The laser diode as claimed in claim 1, wherein said first quantum well structure includes three of said first quantum wells.

6. The laser diode as claimed in claim 1, wherein said first and second quantum well structures are made of the same material selected from the group consisting of Group II-VI semiconductors, Group III-V semiconductors, and Group IV semiconductors.

7. The laser diode as claimed in claim 6, wherein said first and second quantum well structures are made of a composition having a formula of InₓGa_{1-x-y}Al_{y}As, wherein x, y, and 1-x-y range from 0 to 1.

8. The laser diode as claimed in claim 7, wherein said first and second quantum well structures are made of a composition Of In_{0.68}Ga_{0.19}Al_{0.14}As.

9. The laser diode as claimed in claim 1, wherein said spike is made of a composition having a formula of In_{0.52}Ga_{0.209}Al_{0.271}As or In_{0.52}Ga_{0.339}Al_{0.141}As.

10. A laser diode using asymmetric quantum wells, comprising:
a N-type semiconductor;
a P-type semiconductor;
a first quantum well structure formed between said N-type semiconductor and said P-type semiconductor and including at least one first quantum well having a first thickness;
a second quantum well structure formed between said N-type semiconductor and said P-type semiconductor and including at least one second quantum well having a second thickness greater than the first thickness of said first quantum well and a lasing wavelength greater than that of said first quantum well; and
a third quantum well structure formed between said N-type semiconductor and said P-type semiconductor and including at least one third quantum well having a third thickness greater than the first thickness of said first quantum well and less than the second thickness of said second quantum well and a lasing wavelength greater than that of said first quantum well and less than that of said second quantum well, said third quantum well being formed with a spike therein.

11. The laser diode as claimed in claim 10, wherein said spike has a thickness ranging from 1 monolayer to 10 monolayers.

12. The laser diode as claimed in claim 10, wherein said third quantum well structure is proximate to said N-type semiconductor, said second quantum well structure is proximate to said P-type semiconductor, and said first quantum well structure is formed between said second and third quantum well structures.

13. The laser diode as claimed in claim 10, wherein said first quantum well structure includes four of said first quantum wells.

14. The laser diode as claimed in claim 13, wherein the first thickness of said first quantum well is 4.3 nm, the second thickness of said second quantum well is 9 nm, the third thickness of said third quantum well is 7.5 nm, and the thickness of said spike is 0.879 nm.

15. The laser diode as claimed in claim 10, wherein said first quantum well structure is proximate to said N-type semiconductor, said second quantum well structure is proximate to said P-type semiconductor, and said third quantum well structure is formed between said first and second quantum well structures.

16. The laser diode as claimed in claim 10, wherein said first quantum well structure includes three of said first quantum wells.

17. The laser diode as claimed in claim 16, wherein the first thickness of said first quantum well is 4.5 nm, the second thickness of said second quantum well is 9 nm, the third thickness of said third quantum well is 7.5 nm, and the thickness of said spike is 0.879 nm.

18. The laser diode as claimed in claim 10, wherein said first, second, and third quantum well structures are made of the same material selected from the group consisting of Group II-VI semiconductors, Group III-V semiconductors, and Group IV semiconductors.

19. The laser diode as claimed in claim 18, wherein said first, second, and third quantum well structures are made of a composition having a formula of InₓGa_{1-x-y}Al_{y}As, wherein x, y, and 1-x-y range from 0 to 1.

20. The laser diode as claimed in claim 19, wherein said first, second, and third quantum well structures are made of a composition of In_{0.68}Ga_{0.19}Al_{0.14}As.

21. The laser diode as claimed in claim 10, wherein said spike is made of a composition having a formula of In_{0.52}Ga_{0.209}Al_{0.271}As or In_{0.52}Ga_{0.339}Al_{0.141}As.
